(19) United States
(12) Patent Application Publication
(10) Pub. No.: US 2025/0254998 A1
(43) Pub. Date: Aug. 7, 2025

(54) PIXEL STRUCTURE AND DISPLAY DEVICE

(71) Applicant: HannsTouch Holdings Company, Tainan City (TW)

(72) Inventor: Sheng-Chia Lin, Tainan City (TW)

(73) Assignee: HannsTouch Holdings Company, Tainan City (TW)

(21) Appl. No.: 18/433,458

(22) Filed: Feb. 6, 2024

(51) Int. Cl. H01L 27/12; H01L 33/38; H01L 33/44

(52) U.S. Cl. CPC H10D 86/60; H10D 86/411; H10D 86/441; H10H 20/831; H10H 20/84

(57) ABSTRACT

Disclosed is a pixel structure including a substrate, two transistors, an insulating layer, and a pixel electrode. The transistors are disposed on the substrate, and the insulating layer is disposed on the substrate and the transistors. The pixel electrode is disposed on the insulating layer and has two notches separated from each other, in which in a top view of the pixel structure, the notches overlap the transistors respectively.

### BACKGROUND OF THE INVENTION

### 1. Field of the Invention

The present invention relates to a pixel structure and a display device.

### 2. Description of the Prior Art

With the development trend of saving conservation and reducing carbon, electronic paper display devices having power saving function are gradually applied to electronic products in daily life. In the electronic paper display device of the prior art, an array substrate is used to control an electronic ink layer to display images. However, in order to reduce the number of photomasks used for manufacturing the array substrate, the pixel electrodes in the array substrate needs to be spaced apart from thin film transistors, so that regions where no electric field is applied are generated. Accordingly, parts of the electronic ink layer overlapping the regions of no electric field are driven by excessively low electric field or no electric field, causing the electronic paper display device to display abnormal images.

### SUMMARY OF THE INVENTION

According to an embodiment, a pixel structure is provided. The pixel structure includes a substrate, two transistors, an insulating layer, and a pixel electrode. The transistors are disposed on the substrate, and the insulating layer is disposed on the substrate and the transistors. The pixel electrode is disposed on the insulating layer and has two notches separated from each other, in which in a top view of the pixel structure, the notches overlap the transistors respectively.

In the pixel structure of the present invention, the notches corresponding to different transistors are separated from each other, so that a width of each notch may be reduced. Accordingly, regions where no electric field is applied from the pixel electrode may be reduced, thereby preventing the problem of abnormal images generated by the display device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a display device according to an embodiment of the present invention.

FIG. 2 is a schematic top view of a part of a display device corresponding to the front panel laminate according to an embodiment of the present invention.

FIG. 3 is a schematic top view of a part of the display device corresponding to the array substrate according to an embodiment of the present invention.

FIG. 4 is a schematic cross-sectional view taken along a section line A-A′ of FIG. 3.

### DETAILED DESCRIPTION

In order to enable those skilled in the art to further understand the present invention, embodiments of the present invention are listed below, and the composition and intended effects of the present invention will be described in detail with reference to the accompanying drawings. It should be noted that the drawings are simplified schematic diagrams, therefore, only the elements and combination relationships related to the present invention are shown to provide a clearer description of the basic architecture or implementation method of the present invention, while the actual elements and layout may be more complicated. In addition, for convenience of explanation, the elements shown in the various drawings of the present invention are not drawn to the actual number, shape and size, and the detailed scale can be adjusted according to the design requirements.

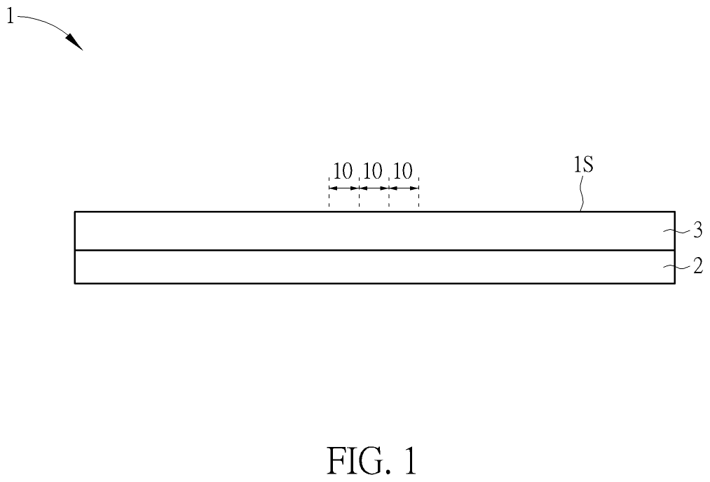

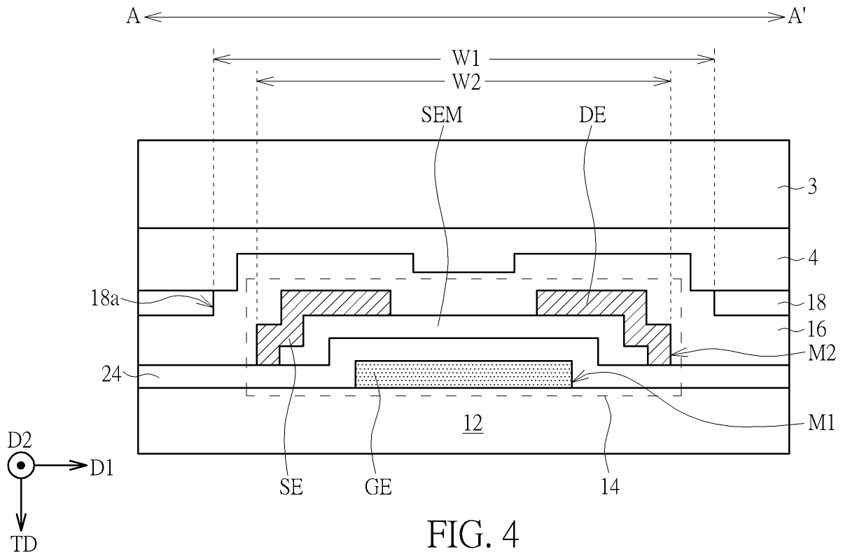

FIG. 1 is a schematic cross-sectional view of a display device according to an embodiment of the present invention. As shown in FIG. 1, the display device 1 may include an array substrate 2 and a front panel laminate (FPL) 3, and the front panel laminate 3 may be disposed on the array substrate 2. For example, the front panel laminate 3 may be attached to the array substrate 2 through an adhesive layer (e.g., an adhesive layer 4 shown in FIG. 4). The front panel laminate 3 may be used to display images, and a surface of the front panel laminate 3 facing away from the array substrate 2 may be referred to as a display surface 1S of the display device 1. The array substrate 2 may be used to control the front panel laminate 3 to display the images on the display surface 1S of the display device 1. The array substrate 2 and the front panel laminate 3 of the display device 1 may include a plurality of pixel structures 10, in which each pixel structure 10 may be used to display a pixel or a sub-pixel of a single color in a corresponding one of the images, for example.

In an embodiment, the front panel laminate 3 may include a display medium layer for displaying the images. For example, the display medium layer may be an electronic ink layer, and in this case, the display device 1 may be an electronic paper display device, but not limited thereto. The electronic ink layer may include electrophoresis, cholesterol liquid crystal or other suitable materials. In some embodiments, the display medium layer may be other types of reflective display media. In some embodiments, the front panel laminate 3 may further include a common electrode (not shown), and the display medium layer may be disposed between the array substrate 2 and the common electrode, but not limited thereto.

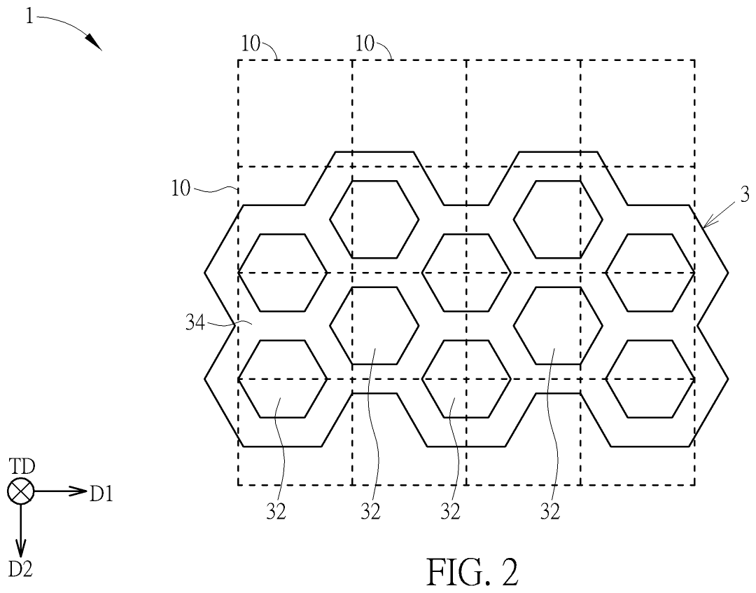

FIG. 2 is a schematic top view of a part of a display device corresponding to the front panel laminate according to an embodiment of the present invention, in which FIG. 2 omits detailed structure of the array substrate (e.g., the array substrate 2 of FIG. 1), but not limited thereto. As shown in FIG. 2, the front panel laminate 3 may include a plurality of display regions 32 and a dark region 34, in which the display regions 32 may be used to display the images, and the dark region 34 cannot display the images or colors and is a black region. For example, the front panel laminate 3 may include a plurality of microcapsules, each of which includes liquid and charged particles with colors, and the charged particles are disposed in the liquid. Each microcapsule may respectively correspond to one of the display regions 32, and by controlling the positions of the charged particles, the display region 32 may show different colors or grayscales, but the present invention is not limited thereto. In some embodiments, the charged particles may have plural colors, or the liquid may have a different color from that of the charged particles, but not limited thereto. Since the charged particles used to display colors in different microcapsules are separated by capsules, the dark region 34 that cannot display colors is formed at boundary between adjacent microcapsules and is located between the display regions 32. In the embodiment of FIG. 2, a size or top view area of one of the display regions 32 may be, for example, less than a size or top view area of one of the pixel structures 10.

As shown in FIG. 2, the display regions 32 are not respectively aligned with the pixel structures 10 in a top view of the display device 1. For example, the display regions 32 are arranged in a honeycomb, and the pixel structures 10 are arranged in an array. A row direction of the pixel structures 10 may be a first direction D1, and a column direction of the pixel structures 10 may be a second direction D2, but not limited thereto. The first direction D1 may, for example, be perpendicular to the second direction D2. A top view shape of one of the display regions 32 may, for example, be different from a top view shape of one of the pixel structures 10. The top view shape of the display region 32 may be, for example, a hexagon or other suitable shapes. The top view shape of the pixel structure 10 may be, for example, a rectangle or other suitable shapes. A pitch between two adjacent display regions 32 projected onto the first direction D1 may be different from a pitch of two adjacent pixel structures 10 arranged in the first direction D1, and/or a pitch between the two adjacent display regions 32 projected onto the second direction D2 may be different from a pitch between two adjacent pixel structures 10 arranged in the second direction D2. For example, the pitch between two adjacent display regions 32 may be substantially 150 micrometers (μm), and the pitch between two adjacent pixel structures 10 may be substantially 167 μm, but not limited thereto. The arrangement of the display regions 32, the arrangement of the pixel structures 10 and relation between the display regions 32 and the pixel structures 10 in the present invention are not limited to FIG. 2 and may be adjusted according to requirements. The pitch mentioned herein may be, for example, a distance between centers of two adjacent elements.

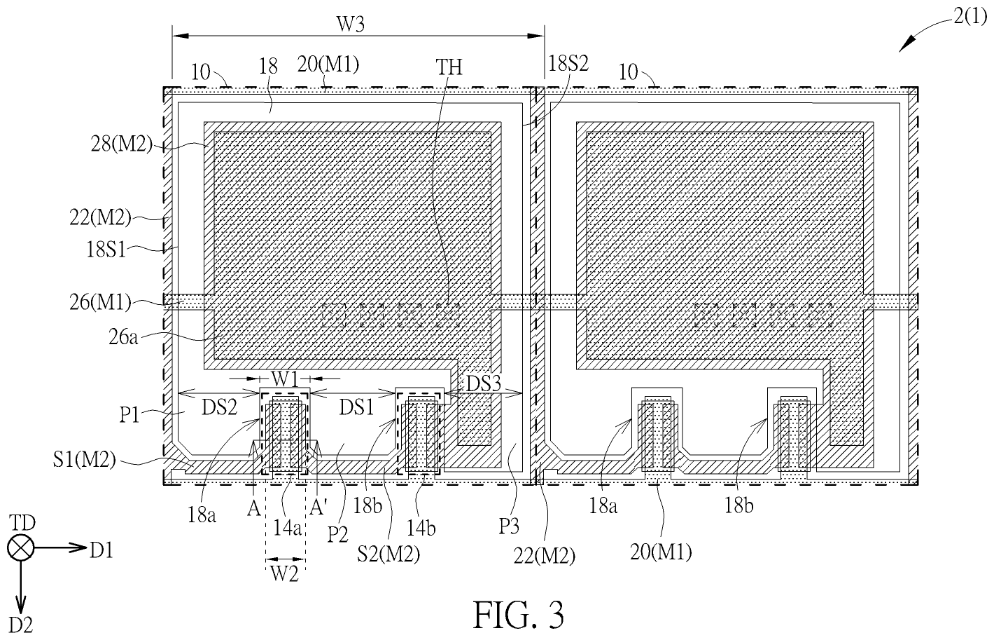

FIG. 3 is a schematic top view of a part of the display device corresponding to the array substrate according to an embodiment of the present invention, and FIG. 4 is a schematic cross-sectional view taken along a section line A-A′ of FIG. 3, in which in order to clearly show the pixel structures 10 located in the array substrate 2, and the front panel laminate (e.g., the front panel laminate 3 shown in FIG. 1) is omitted in FIG. 3, but not limited thereto. As shown in FIG. 3 and FIG. 4, one of the pixel structures 10 may include a substrate 12, two transistors 14a, 14b, an insulating layer 16, and a pixel electrode 18, in which the transistors 14a, 14b are disposed on the substrate 12, the insulating layer 16 is disposed on the substrate 12 and the transistors 14a, 14b, and the pixel electrode 18 is disposed on the insulating layer 16. In addition, the pixel electrode 18 has two notches 18a, 18b separated from each other, and the notches 18a, 18b overlap the transistors 14a, 14b respectively in the top view of the pixel structure 10. It should be noted that by separating the notches 18a, 18b corresponding to different transistors 14a, 14b, a width W1 of each notch 18a, 18b may be reduced so as to decrease the regions with no electric field applied by the pixel electrode 18. Accordingly, the problem of abnormal images generated by the display device 1 can be avoided.

In one embodiment, the pixel electrode 18 may not overlap the transistors 14a, 14b in a top view direction TD of the pixel structure 10 to reduce the influence of the pixel electrode 18 on the transistors 14a, 14b, thereby avoiding leakages of the transistors 14a, 14b. For example, the width W1 of one of the notches 18a, 18b in the first direction D1 may be substantially greater than a width W2 or 0.5 times the width W2 of one of the transistors 14a, 14b in the first direction D1, so as to reduce the influence of the pixel electrode 18 on the transistors 14a, 14b while reducing the sizes of the regions where no electric field is applied. In order to reduce the sizes of the regions where no electric field is applied, the width W1 may be less than 4 or 5 times the width W2, but not limited thereto. In some embodiments, the width W1 of the notch 18a may be the same as or different from the width W1 of the notch 18b.

In detail, in one of the pixel structures 10, the notches 18a, 18b may be arranged along the first direction D1, and a distance DS1 between the notches 18a, 18b separated from each other may be less than or equal to two thirds of a width W3 of the pixel structure 10 in the first direction D1. Alternatively, the distance DS1 may be less than or equal to a half of the width W3 of the pixel structure 10 in the first direction D1. By designing the distance DS1 to be less than or equal to a certain proportion of the width W3 of the pixel structure 10, the distance between the notch 18a of one pixel structure 10 and the notch 18b of another pixel structure 10 adjacent thereto may be prevented from being too small, so as to avoid the problem of poor images due to the regions where no electric field is applied being too close. Specifically, the pixel electrode 18 may have a first portion P1, a second portion P2 and a third portion P3, in which the notch 18a may be located between the first portion P1 and the second portion P2, and the notch 18b may be located between the second portion P2 and the third portion P3. Also, the distance DS1 may be a width of the second portion P2 in the first direction D1.

In addition, a minimum value of the distance DS1 between the notches 18a, 18b that are spaced apart from each other may depend on limit of manufacturing process of the notches 18a, 18b. For example, the distance DS1 between the notches 18a, 18b may be greater than or equal to 1 μm, 5 μm or 8 μm in some manufacturing processes, but not limited thereto. In some embodiments, the distance DS1 between the notches 18a, 18b may be greater than or equal to the width W2 of one of the transistors 14a, 14b in the first direction D1, such that the distance DS1 between the notches 18a, 18b of the same pixel structure 10 will not be too small. Accordingly, the problem of abnormal images caused by the regions of no electric field too close to each other can be avoided.

As shown in FIG. 3, the pixel electrode 18 may have two opposite sides 18S1, 18S2, and the notches 18a, 18b are disposed between the sides 18S1, 18S2 and separated from the sides 18S1, 18S2, such that the distance between the notch 18b and the notch 18a of two adjacent pixel electrodes 18 will not be too small to avoid the problem of abnormal images. In one of the pixel structures 10, the notch 18a may be disposed between the side 18S1 of the pixel electrode 18 and the notch 18b, and a distance DS2 between the notch 18a and the side 18S1 may be greater than or equal to the limit of the manufacturing process, for example, be 1 μm, 5 μm or 8 μm, but not limited thereto. In some embodiments, a distance DS3 between the notch 18b and the side 18S2 may be greater than or equal to the limit of the manufacturing process, but not limited thereto. In some embodiments, the pixel electrode 18 may, for example, include metal or transparent conductive material. The transparent conductive material may include, for example, indium tin oxide (ITO) or other suitable materials.

As shown in FIG. 3 and FIG. 4, the plurality of pixel structures 10 may further include a plurality of scan lines 20 and a plurality of data lines 22. In the embodiment of FIG. 3, the scan lines 20 may extend along the first direction D1 and be arranged in the second direction D2, and the data lines 22 may extend along the second direction D2 and be arranged in the first direction D1, but not limited thereto. The first direction D1 may be different from the second direction D2, and for example, the first direction D1 is perpendicular to the second direction D2. In this embodiment, one of the pixel structures 10 may be defined, for example, by a region surrounded by two adjacent scan lines 20 and two adjacent data lines 22, and each pixel structure 10 may include a part of one of the scan lines 20 and a part of one of the data lines 22. In this case, the width W3 of the pixel structure 10 in the first direction D1 may, for example, be defined as a distance between a side of an element in one of the pixel structures 10 and a corresponding side of the same element as the element of the pixel structure 10 in the adjacent pixel structure 10. For example, the width W3 of the pixel structure 10 may be the distance between right sides of two adjacent data lines 22. The pixel structures 10 in the present invention are not limited to the definition mentioned above, and the definition of the pixel structures 10 may be adjusted according to configurations.

In addition, in the embodiment of FIG. 3, one of the scan lines 20 may be electrically connected to the transistors 14a, 14b of the pixel structures 10 arranged in the same row, and in the top view of one of the pixel structures 10, the notches 18a, 18b may face the scan line 20. One of the data lines 22 may be electrically connected to the transistors 14a of the pixel structures 10 arranged in the same column, and each data line 22 may be electrically connected to the corresponding pixel electrode 18 through the corresponding transistors 14a, 14b.

As shown in FIG. 4, taking the transistor 14a as an example, only the insulating layer 16 may be disposed between the transistor 14a and the pixel electrode 18, so as to reduce the number of photmasks for manufacturing the array substrate. In this case, the insulating layer 16 may directly contact the transistor 14a and the pixel electrode 18, but not limited thereto.

As shown in FIG. 3 and FIG. 4, the transistors 14a, 14b in this embodiment may be, for example, bottom gate type thin film transistors. The transistors 14a, 14b may have the same or similar structure. In FIG. 4, the transistor 14a is taken as an example, but not limited thereto. The transistor 14a may include a gate electrode GE, a gate insulating layer 24, a semiconductor island SEM, a source electrode SE, and a drain electrode DE. The gate electrode GE may be disposed on the substrate 12, and the gate insulating layer 24 may be disposed on the gate electrode GE and the substrate 12. The semiconductor island SEM may be disposed on the gate insulating layer 24 and correspond to the gate electrode GE in the top view direction TD, and the source electrode SE and the drain electrode DE may be disposed on the semiconductor island SEM and are located on two opposite parts of the semiconductor island SEM respectively. Taking the transistor 14a as an example, the width W2 of the transistor 14a may be a distance between a side of the source electrode SE away from the drain electrode DE and a side of the drain electrode DE away from the source electrode SE, but not limited thereto. In the embodiment of FIG. 3, the source electrode SE of the transistor 14a is electrically connected to the drain electrode DE of the transistor 14b, and the drain electrode DE of the transistor 14b is electrically connected to the pixel electrode 18.

In one embodiment, the gate electrodes GE and the scan lines 20 may be formed of the same first conductive layer M1, and the source electrodes SE, the drain electrodes DE, and the data lines 22 may be formed of the same second conductive layer M2, but not limited thereto. In this case, one of the gate electrodes GE may be directly connected to the corresponding scan line 20. The second conductive layer M2 may further include a first line segment S1 and a second line segment S2, in which the source electrode SE of the transistor 14a may be electrically connected to the data line 22 through the first line segment S1, and the source electrode SE of the transistor 14b may be electrically connected to the drain electrode DE of the transistor 14a through the second line segment S2. When viewed along the top view direction TD, the first line segment S1 may be located between the first portion P1 of the pixel electrode 18 and the scan line 20, and the second line segment S2 may be located between the second portion P2 of the pixel electrode 18 and the scan line 20, but not limited thereto. The first conductive layer M1 and the second conductive layer M2 may include metal, for example. In some embodiments, the transistors 14a, 14b may be other types of thin film transistors, but not limited thereto.

As shown in FIG. 3 and FIG. 4, the pixel structure 10 may further include a storage electrode 28 formed of the second conductive layer M2. The storage electrode 28 may overlap the pixel electrode 18 in the top view direction TD, and the insulating layer 16 may have a through hole TH, so that the pixel electrode 18 may be electrically connected to the storage electrode 28 through the through hole TH. Also, the first conductive layer M1 may further include a common line 26, and the common line 26 may have an electrode portion 26a, in which the electrode portion 26a overlaps the storage electrode 28 in the top view direction TD, so that the electrode portion 26a, the gate insulating layer 24 and the storage electrode 28 may form a storage capacitor, but not limited thereto. In an embodiment, the common line 26 may extend along the first direction D1, but not limited thereto.

As mentioned above, in the pixel structure of the present invention, by separating the notches corresponding to different transistors, the width of each notch may be reduced to decrease the regions where no electric field is applied by the pixel electrode. Accordingly, the problem of abnormal images generated by the display device is avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A pixel structure, comprising:
a substrate;
two transistors disposed on the substrate;
an insulating layer disposed on the substrate and the transistors; and
a pixel electrode disposed on the insulating layer, and the pixel electrode having two notches separated from each other, wherein in a top view of the pixel structure, the notches overlap the transistors respectively.

2. The pixel structure as claimed in claim 1, wherein the notches are arranged along a direction, and a distance between the notches is less than or equal to two thirds of a width of the pixel structure in the direction.

3. The pixel structure as claimed in claim 2, wherein the distance is greater than or equal to a width of one of the transistors in the direction.

4. The pixel structure as claimed in claim 1, wherein the pixel electrode has two sides opposite to each other, and the notches are disposed between the sides and separated from the sides.

5. The pixel structure as claimed in claim 4, wherein one of the notches is disposed between one of the sides and another one of the notches, and a distance between the one of the notches and the one of the sides is greater than 1 micrometer.

6. The pixel structure as claimed in claim 1, wherein the notches are arranged along a direction, and a width of one of the notches in the direction is greater than 0.5 times a width of one of the transistors in the direction.

7. The pixel structure as claimed in claim 1, wherein the notches are arranged along a direction, and a width of one of the notches is less than 5 times a width of one of the transistors in the direction.

8. A display device, comprising:
an array substrate; and
a front panel laminate disposed on the array substrate, and the array substrate and the front panel laminate comprising a plurality of the pixel structures as claimed in claim 1.

9. The display device as claimed in claim 8, wherein the front panel laminate comprises a plurality of display regions, and the display regions are not aligned to the pixel structures in a top view of the display device.

10. The display device as claimed in claim 9, wherein one of the pixel structures overlaps at least two of the display regions in the top view of the display device.
